(19) United States
(12) Patent Application Publication
(10) Pub. No.: US 2025/0142883 A1
(43) Pub. Date: May 1, 2025

(54) SEMICONDUCTOR STRUCTURE WITH DEVICES HAVING DIFFERENT EFFECTIVE CHANNELS AND REDUCED EFFECTIVE CAPACITANCES, AND METHOD FOR MANUFACTURING THE SAME

(71) Applicant: TAIWAN SEMICONDUCTOR MANUFACTURING COMPANY, LTD., Hsinchu (TW)

(72) Inventors: Jung-Hung CHANG, Hsinchu (TW); Tsung-Han CHUANG, Hsinchu (TW); Fu-Cheng CHANG, Hsinchu (TW); Shih-Cheng CHEN, Hsinchu (TW); Chia-Cheng TSAI, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 18/499,816

(22) Filed: Nov. 1, 2023

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0128; H10D 84/013; H10D 84/0151; H10D 84/038; H10D 84/83

(57) ABSTRACT

A semiconductor device includes two source/drain regions, two isolation elements, a channel feature, at least one semiconductor layer and a gate feature. The source/drain regions are spaced apart from each other, and are respectively disposed above the isolation elements. The channel feature includes at least one effective channel layer and at least one dummy channel layer that are spaced apart from each other. Each of the at least one effective channel layer extends between the source/drain regions. Each of the at least one dummy channel layer extends between the isolation elements. The at least one semiconductor layer at least covers a lower surface of a bottommost one of the at least one dummy channel layer. The gate feature is disposed around the at least one effective channel layer, such that two opposite surfaces of each of the at least one effective channel layer are adjacent to the gate feature.

### BACKGROUND

While the critical dimension (CD) of transistors continues to shrink and various three-dimensional (3D) transistor structures (e.g., a gate-all-around (GAA) structure, a forksheet structure, etc.) continue to be developed for manufacturing integrated circuits (ICs) with high integration densities, there is still a need for transistors having a much wider range of specifications (e.g., extreme-low power consumption, extreme-high-speed computing, etc.) to facilitate the design of integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are schematic sectional views cooperatively showing a semiconductor structure in accordance with some embodiments.

FIG. 3 is a schematic sectional view taken along line A-A of FIG. 1, and FIG. 4 is a schematic sectional view taken along line B-B of FIG. 2.

FIG. 5 is a flow chart illustrating a method for manufacturing a semiconductor structure in accordance with some embodiments.

FIGS. 6 to 30 are schematic sectional views illustrating intermediate stages of the method for manufacturing a semiconductor structure in accordance with some embodiments, where FIG. 7 is taken along any one of line C-C and line D-D of FIG. 6. FIGS. 8, 10, 12, 14, 17, 20, 23, 25 and 28 are similar to FIG. 6, FIGS. 9, 11 and 13 are similar to FIG. 7, FIGS. 15, 18 and 21 are schematic sectional views taken along line C-C of FIG. 14, line C-C of FIG. 17 and line C-C of FIG. 20, FIGS. 16, 19 and 22 are schematic sectional views taken along line D-D of FIG. 14, line D-D of FIG. 17 and line D-D of FIG. 20, FIG. 24 is taken along any one of line E-E and line F-F of FIG. 23, FIGS. 26 and 29 are schematic sectional views taken along line E-E of FIG. 25 and line E-E of FIG. 28, and FIGS. 27 and 30 are schematic sectional views taken along line F-F of FIG. 25 and line F-F of FIG. 28.

FIGS. 31 and 32 are schematic sectional views cooperatively showing a semiconductor structure in accordance with some embodiments.

FIGS. 33 and 34 are schematic sectional views cooperatively showing a semiconductor structure in accordance with some embodiments, where FIG. 33 is taken along line A-A of FIG. 1, and FIG. 34 is taken along line B-B of FIG. 2.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

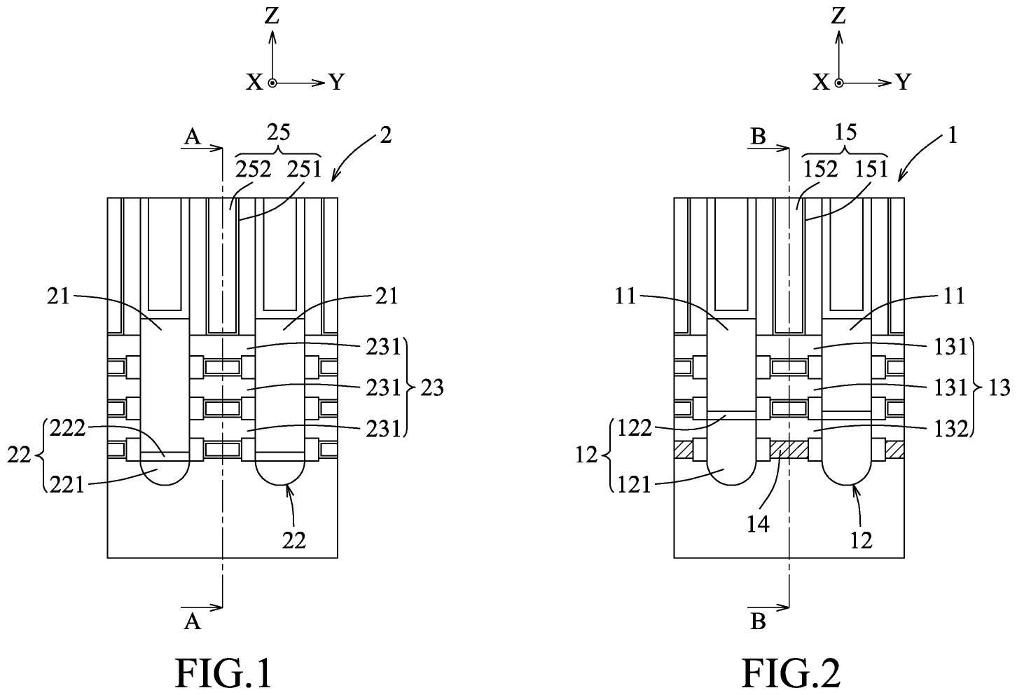

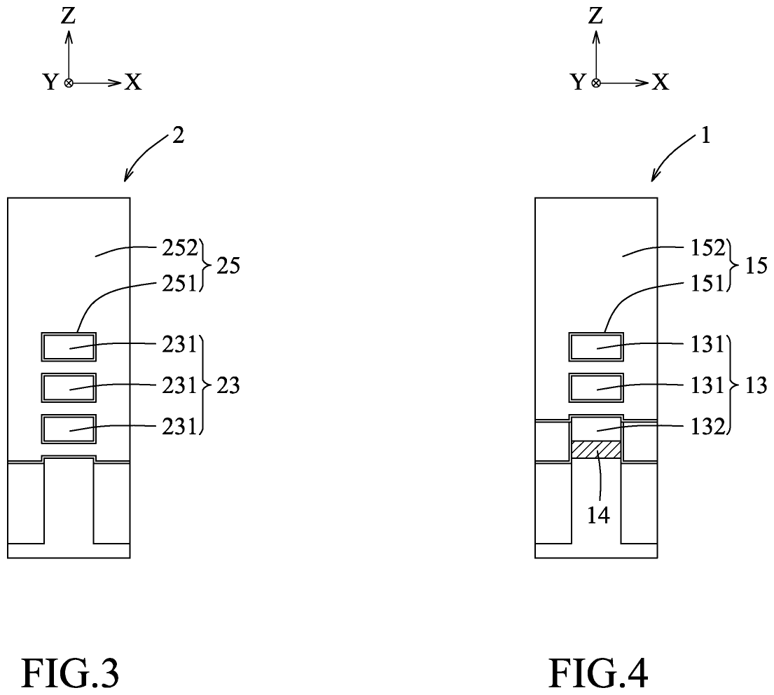

FIGS. 1 to 4 are schematic sectional views cooperatively showing a semiconductor structure in accordance with some embodiments, where FIG. 3 is taken along line A-A of FIG. 1, and FIG. 4 is taken along line B-B of FIG. 2. The semiconductor structure includes a first device 1 and a second device 2.

The first device 1 includes two first source/drain regions 11, two isolation elements 12, a first channel feature 13, at least one semiconductor layer 14 and a first gate structure 15. The first source/drain regions 11 are spaced apart from each other in a first direction (e.g., a Y direction) transverse to a second direction (e.g., a Z direction) from bottom to top of the semiconductor structure. Each of the isolation elements 12 is disposed below a respective one of the first source/drain regions 11. The first channel feature 13 includes at least one first effective channel layer 131 and at least one dummy channel layer 132 that are spaced apart from each other in the Z direction. Each of the at least one first effective channel layer 131 extends between the two first source/drain regions 11. Each of the at least one dummy channel layer 132 extends between the two isolation elements 12. The at least one semiconductor layer 14 at least covers a lower surface of a bottommost one of the at least one dummy channel layer 132. The first gate feature 15 is disposed around the at least one first effective channel layer 131 such that two surfaces of each of the at least one first effective channel layer 131, which are opposite to each other in the Z direction, are both adjacent to the first gate feature 15. The first gate feature 15 includes a first gate electrode 152, and a first gate dielectric 151 disposed to separate the first gate electrode 152 from the at least one first effective channel layer 131.

In some embodiments, each of the isolation elements 12 includes a first isolation segment 121 that is made of an un-doped semiconductor material (e.g., un-doped silicon), and a second isolation segment 122 that is disposed between the first isolation segment 121 and the respective one of the first source/drain regions 11 and that is made of a dielectric material (e.g., silicon nitride, silicon oxycarbide, silicon oxycarbonitride or silicon carbonitride). In some embodiments, a thickness of the second isolation segment 122 of each of the isolation elements 12 in the Z direction is smaller than a thickness of each of the at least one first effective channel layer 131 and the at least one dummy channel layer 132 in the Z direction.

The second device 2 includes two second source/drain regions 21, two filled elements 22, a second channel feature 23 and a second gate structure 25. The second source/drain regions 21 are spaced apart from each other in the Y direction. The second channel feature 23 includes a plurality of second effective channel layers 231 that are spaced apart from each other in the Z direction. Each of the second effective channel layers 231 extends between the two second source/drain regions 21. A total number of the second effective channel layers 231 is equal to a total number of the at least one first effective channel layer 131 and the at least one dummy channel layer 132. Each of the filled elements 22 is disposed below a respective one of the second source/drain regions 21, and is kept away from contact with the second effective channel layers 231. The second gate feature 25 is disposed around the second effective channel layers 231 such that two surfaces of each of the second effective channel layers 231, which are opposite to each other in the Z direction, are both adjacent to the second gate feature 25. The second gate feature 25 includes a second gate electrode 252, and a second gate dielectric 151 disposed to separate the second gate electrode 252 from the second effective channel layers 231.

In some embodiments, each of the filled elements 22 includes a first filled segment 221 that is made of an un-doped semiconductor material (e.g., un-doped silicon), and a second filled segment 222 that is disposed between the first filled segment 221 and the respective one of the second source/drain regions 21 and that is made of a dielectric material (e.g., silicon nitride, silicon oxycarbide, silicon oxycarbonitride or silicon carbonitride). In some embodiments, a thickness of the second filled segment 222 of each of the filled elements 22 in the Z direction is smaller than a thickness of each of the second effective channel layers 231 in the Z direction.

FIGS. 1 to 4 depict an example where there are two first effective channel layers 131, one dummy channel layer 132, one semiconductor layer 14 and three second effective channel layers 231.

Since the total number of the first effective channel layers 131 is smaller than the total number of the second effective channel layers 231, an effective channel width of the first device 1 is smaller than an effective channel width of the second device 2, and hence the first device 1 may meet the requirement of low power consumption, and the second device 2 may meet the requirement of high computing speed.

By virtue of the second isolation segments 122 of the isolation elements 12 and the second filled segments 222 of the filled elements 22 that are made of a dielectric material, mesa leakages in the semiconductor structure can be restrained.

By virtue of the at least one semiconductor layer 14, a thickness of the first gate electrode 152 in the Z direction can be reduced, thereby reducing effective capacitances of the first device 1.

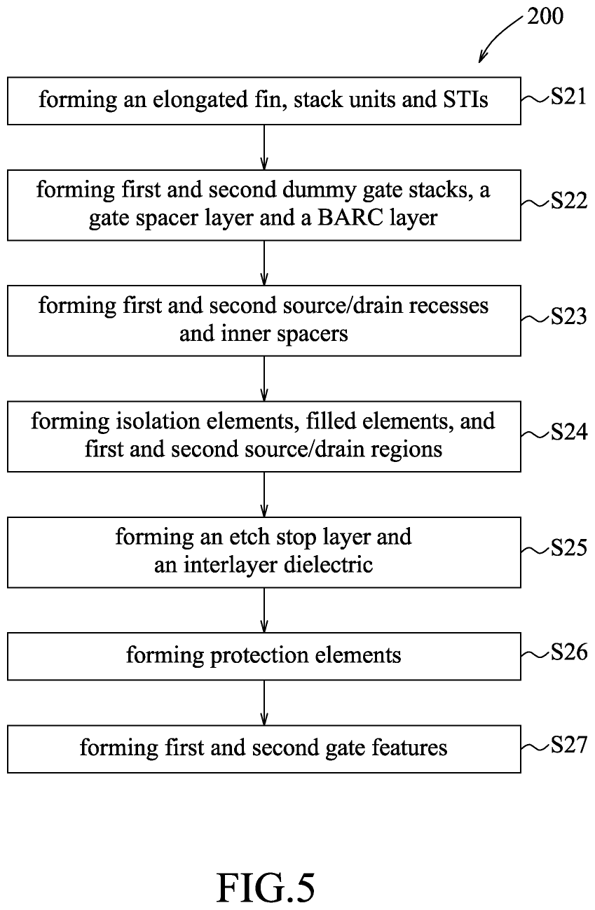

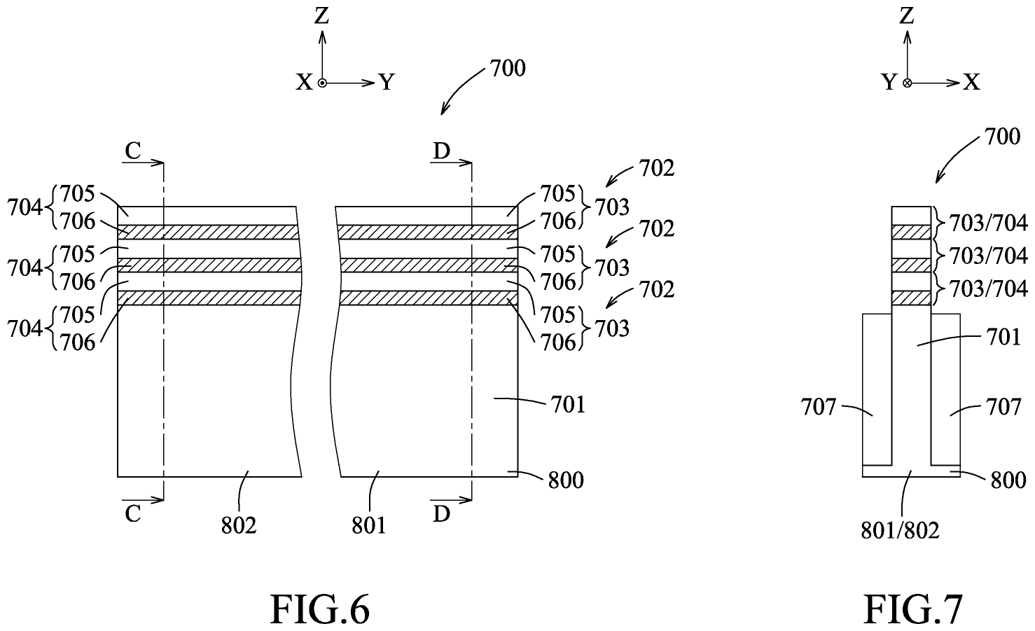

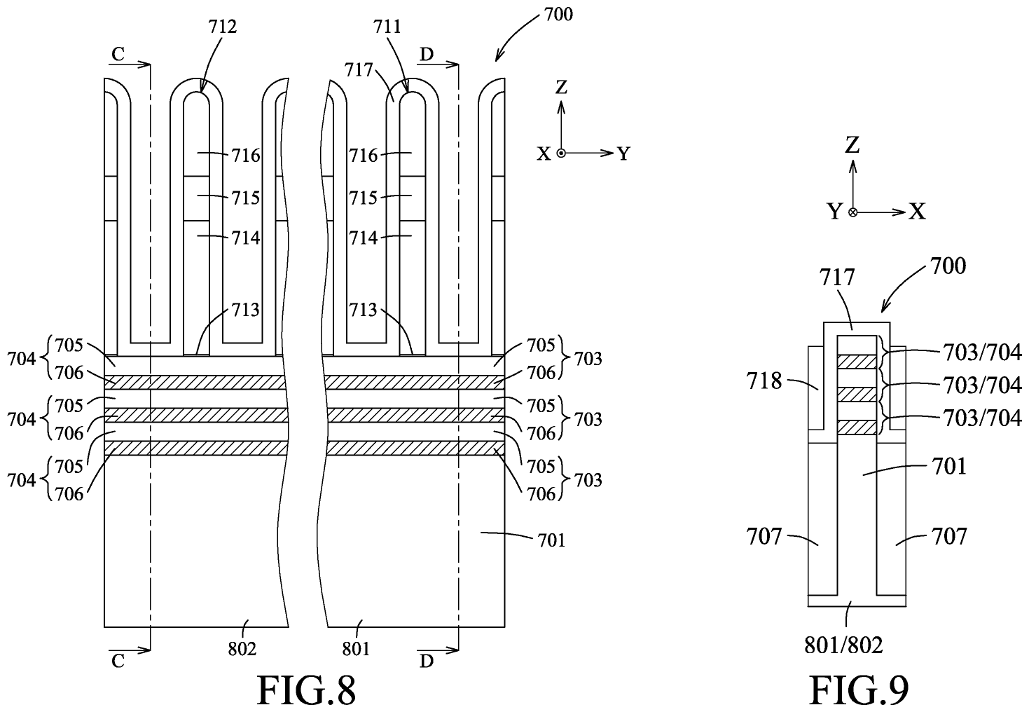

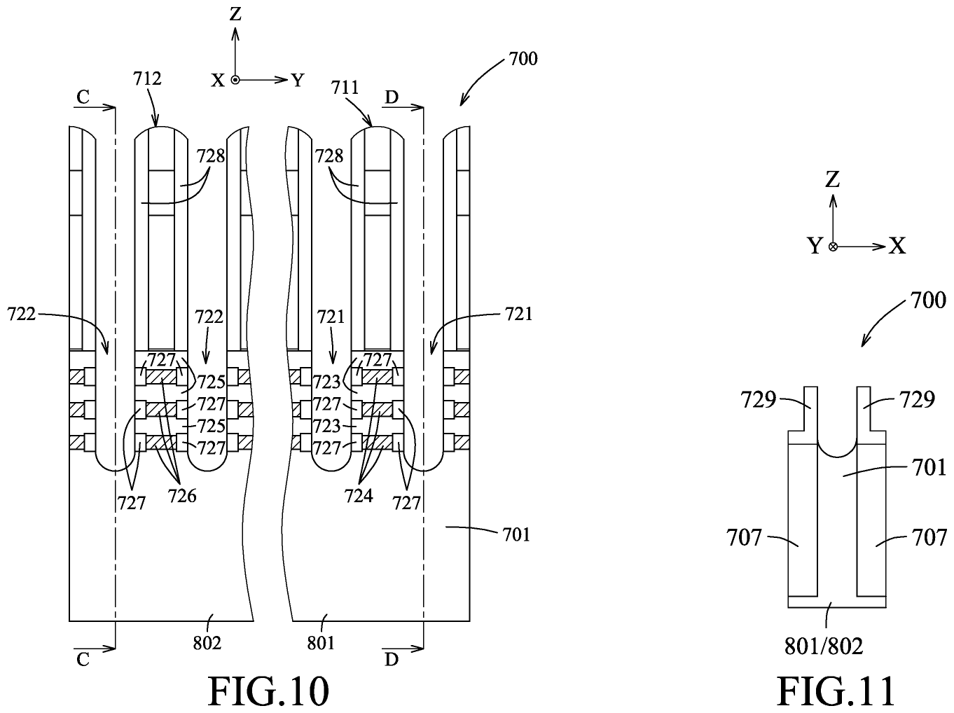

FIG. 5 is a flow chart illustrating a method 200 for manufacturing a semiconductor structure in accordance with some embodiments. FIGS. 6 to 30 are schematic sectional views of semiconductor structures 700 during various stages of the method 200. The method 200 and the semiconductor structures 700 will be described below. Additional steps can be provided before, after or during the method 200, and some of the steps described herein may be replaced by other steps or be eliminated. Similarly, further additional features may be present in the semiconductor structures 700, and/or features present may be replaced or eliminated in additional embodiments.

Referring to FIGS. 5, 6 and 7, where FIG. 7 illustrates a schematic sectional view taken along any one of line C-C and line D-D of FIG. 6, the method 200 begins at step S21, where an elongated fin 701, a plurality of stack units 702 and two shallow trench isolations (STIs) 707 are formed on a substrate 800. FIGS. 6 and 7 depict an example where there are three stack units 702. The substrate 800 includes a first region 801 that is designed to form the first device 1 (see FIGS. 2 and 4) thereon, and a second region 802 that is designed to form the second device 2 (see FIGS. 1 and 3) thereon. The elongated fin 701 is disposed on the substrate 800, and extends in a first direction (e.g., a Y direction) transverse to a second direction (e.g., a Z direction) from bottom to top of the semiconductor structure 700. The stack units 702 are disposed on the elongated fin 701. Each of the stack units 702 includes a first stack 703 corresponding to the first region 801 in position, and a second stack 704 corresponding to the second region 802 in position. Each of the first and second stacks 703, 704 of the stack units 702 includes a channel film 705, and a semiconductor film 706 disposed below the channel film 705. The STIs 707 are disposed on the substrate 800, and are respectively disposed at two opposite sides of the elongated fin 701 in a third direction (e.g., a X direction) transverse to the Y direction and the Z direction. An upper surface of each of the STIs 707 is lower than an upper surface of the elongated fin 701. In some embodiments, the elongated fin 701 and the stack units 702 may be formed by: (a) depositing multiple first semiconductor sheets for forming the channel films 705 of the first and second stacks 703, 704 of the stack units 702 and multiple second semiconductor sheets for forming the semiconductor films 706 of the first and second stacks 703, 704 of the stack units 702 on the substrate 800 in an alternating manner using, for example, chemical vapor deposition (CVD), plasma enhanced chemical vapor deposition (PECVD), physical vapor deposition (PVD), atomic layer deposition (ALD), other suitable techniques, or combinations thereof; and (b) patterning the first semiconductor sheets, the second semiconductor sheets and the substrate 800 to form the channel films 705, the semiconductor films 706 and the elongated fin 701. In some embodiments, the first semiconductor sheets, the second semiconductor sheets and the substrate 800 may be patterned using a photolithography process and an etching process. The photolithography process may include, for example, but not limited to, coating a topmost one of the first semiconductor sheets, the second semiconductor sheets and the substrate 800 with a photoresist, soft-baking, exposing the photoresist through a photomask, post-exposure baking, developing the photoresist, and hard-baking, so as to form a patterned photoresist. The etching process may be implemented by etching the first semiconductor sheets, the second semiconductor sheets and the substrate 800 through the patterned photoresist using, for example, dry etching, wet etching, reactive ion etching (RIE), atomic layer etching (ALE), other suitable techniques, or combinations thereof. The patterned photoresist may be removed after the etching process. In some embodiments, the STIs 707 may be formed by: (a) depositing a dielectric layer for forming the STIs 707 over the substrate 800 and the stack units 702 using, for example, CVD, PECVD, PVD, ALD, other suitable techniques, or combinations thereof; (b) removing an excess of the dielectric layer using, for example, chemical mechanical polishing (CMP), or other suitable planarization techniques, so as to expose a top surface of the stack units 702; and (c) etching back the dielectric layer using, for example, dry etching, wet etching, RIE, ALE, other suitable techniques, or combinations thereof, so as to form the STIs 707. In some embodiments, the substrate 800 may be a silicon substrate. In some embodiments, the first semiconductor sheets for forming the channel films 705 may be silicon sheets, and the second semiconductor sheets for forming the semiconductor films 706 may be silicon germanium sheets, but the disclosure is not limited in this respect. In some embodiments, the dielectric layer for forming the STIs 707 may include, for example, silicon oxide, silicon nitride, silicon oxynitride, high dielectric constant materials, other suitable materials, or combinations thereof. In some embodiments, a thickness of each of the first semiconductor sheets for forming the channel films 705 may fall within a range of from 4 nm to 10 nm. In some embodiments, the upper surface of each of the STIs 707 is lower than the upper surface of the elongated fin 701 by a distance that may fall within a range of from 5 nm to 10 nm.

Referring to FIGS. 5, 8 and 9, where FIG. 9 is a view similar to FIG. 7, the method 200 then proceeds to step S22, where a first dummy gate stack 711 is formed over the first stacks 703 and the STIs 707, a second dummy gate stack 712 is formed over the second stacks 704 and the STIs 707, a gate spacer layer 717 is formed over the first and second dummy gate stacks 711, 712, the first and second stacks 703, 704 and the STIs 707, and a bottom anti-reflective coating (BARC) layer 718 is formed on the STIs 707 covered by the gate spacer layer 717. Each of the first and second dummy gate stacks 711, 712 extends in the X direction, and includes a dummy gate dielectric 713, a dummy gate electrode 714, a polish-stop layer 715 and a hard mask layer 716 that are arranged from bottom to top in the given order. The gate spacer layer 717 may have a single layer structure or a multi-layered structure. A top surface of the BARC layer 718 is lower than a top surface of a combination of the first stacks 703 and a top surface of a combination of the second stacks 704. In some embodiments, the first and second dummy gate stacks 711, 712 may be formed by: (a) depositing a first layer for forming the dummy gate dielectrics 713 of the first and second dummy gate stacks 711, 712, a second layer for forming the dummy gate electrodes 714 of the first and second dummy gate stacks 711, 712, a third layer for forming the polish-stop layers 715 of the first and second dummy gate stacks 711, 712, and a fourth layer for forming the hard mask layers 716 of the first and second dummy gate stacks 711, 712 using, for example, CVD, PECVD, PVD, ALD, other suitable techniques, or combinations thereof; and (b) patterning the first to fourth layers to form the dummy gate dielectrics 713, the dummy gate electrodes 714, the polish-stop layers 715 and the hard mask layers 716 using a photolithography process and an etching process similar to those used to pattern the first semiconductor sheets, the second semiconductor sheets and the substrate 800 in step S21 of the method 200. In some embodiments, the gate spacer layer 717 may be conformally formed using, for example, CVD, ALD, other suitable techniques, or combinations thereof. In some embodiments, the BARC layer 718 may be formed by: (a) depositing a material for forming the BARC layer 718 using, for example, CVD, PECVD, PVD, ALD, other suitable techniques, or combinations thereof; and (b) etching back the material using, for example, dry etching, wet etching, RIE, ALE, other suitable techniques, or combinations thereof, so as to form the BARC layer 718. In some embodiments, the first layer for forming the dummy gate dielectrics 713 may include, for example, silicon oxide, other suitable dielectric materials, or combinations thereof. In some embodiments, the second layer for forming the dummy gate electrodes 714 may include, for example, polycrystalline silicon, microcrystal silicon, amorphous silicon, other suitable materials, or combinations thereof. In some embodiments, the third layer for forming the polish-stop layers 715 may include, for example, silicon nitride, silicon oxide, other nitrides, other oxides, other suitable materials, or combinations thereof. In some embodiments, the fourth layer for forming the hard mask layers 716 may include, for example, silicon nitride, silicon oxide, silicon oxynitride, other suitable materials, or combinations thereof. In some embodiments, the gate spacer layer 717 may include, for example, silicon nitride, silicon oxycarbide, silicon oxycarbonitride, silicon carbonitride, other suitable materials, or combinations thereof. In some embodiments, the material for forming the BARC layer 718 may include, for example, silicon oxide, silicon nitride, silicon oxynitride, hafnium oxide, tantalum oxide, other suitable dielectric materials, materials suitable for forming a photoresist, or combinations thereof.

Referring to FIGS. 5, 8, 9, 10 and 11, where FIG. 11 is a view similar to FIG. 7, the method 200 then proceeds to step S23, where two first source/drain recesses 721, two second source/drain recesses 722 and a plurality of inner spacers 727 are formed. The first source/drain recesses 721 are formed in the first stacks 703 and the elongated fin 701 at positions exposed from the first dummy gate stack 711 and at portions on the gate spacer layer 717 that laterally cover sidewalls of the first dummy gate stack 711, and are spaced apart from each other in the Y direction, so that the channel films 705 of the first stacks 703 are formed into first channel layers 723 and the semiconductor films 706 of the first stacks 703 are formed into first semiconductor layers 724. The second source/drain recesses 722 are formed in the second stacks 704 and the elongated fin 701 at positions exposed from the second dummy gate stack 712 and at portions on the gate spacer layer 717 that laterally cover sidewalls of the second dummy gate stack 712, so that the channel films 705 of the second stacks 704 are formed into second channel layers 725 and the semiconductor films 706 of the second stacks 704 are formed into second semiconductor layers 726. In some embodiments, the first and second source/drain recesses 721, 722 may be formed by etching the first stacks 703, the second stacks 704 and the elongated fin 701 using, for example, dry etching, wet etching, RIE, ALE, other suitable techniques, or combinations thereof. At the same time, some of horizontal portions of the gate spacer layer 717 that are exposed from the BARC layer 718 are removed. Some vertical portions of the gate spacer layer 717 that remain on the sidewalls of the first and second dummy gate stacks 711, 712 serve as gate spacers 728. Some the vertical portions of the gate spacer layer 717 that remain on the STIs 707 serve as fin sidewalls 729. The BARC layer 718 may be removed after the first and second source/drain recesses 721, 722 are formed. Thereafter, the first and second semiconductor layers 724, 726 are etched to form recesses at side portions thereof, and the inner spacers 727 are formed to fill the recesses. In some embodiments, the first and second semiconductor layers 724, 726 may be etched using, for example, dry etching, wet etching, RIE, ALE, other suitable techniques, or combinations thereof. In some embodiments, the inner spacers 727 may include, for example, oxide-based material (e.g., silicon oxide), carbide-based material (e.g., silicon carbide), oxynitride-based material (e.g., silicon oxynitride), nitride-based material (e.g., silicon nitride), other suitable dielectric materials, or combinations thereof.

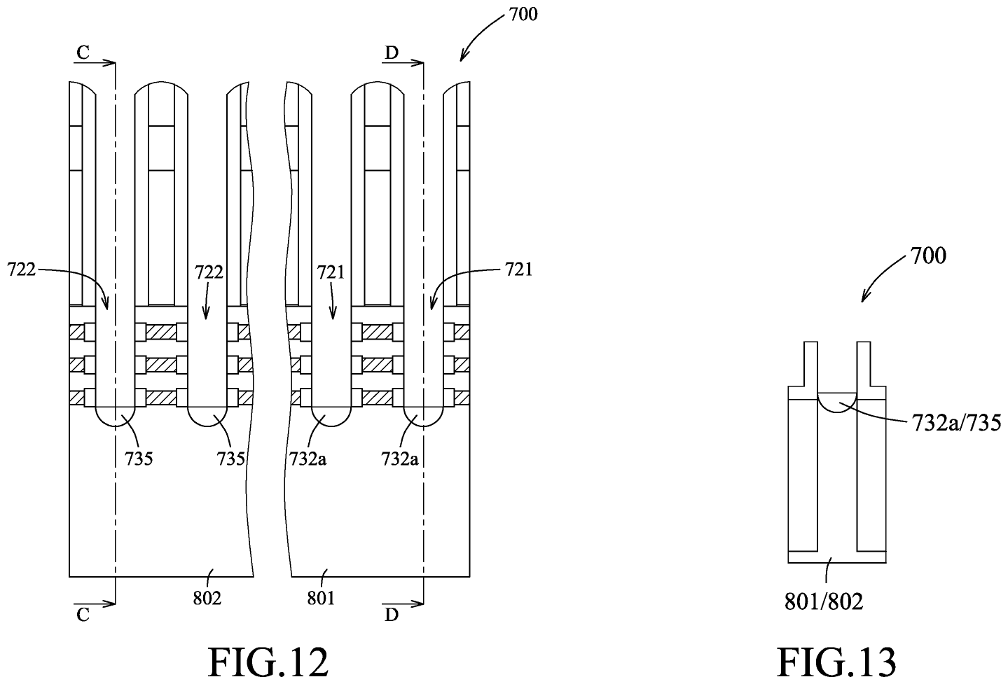

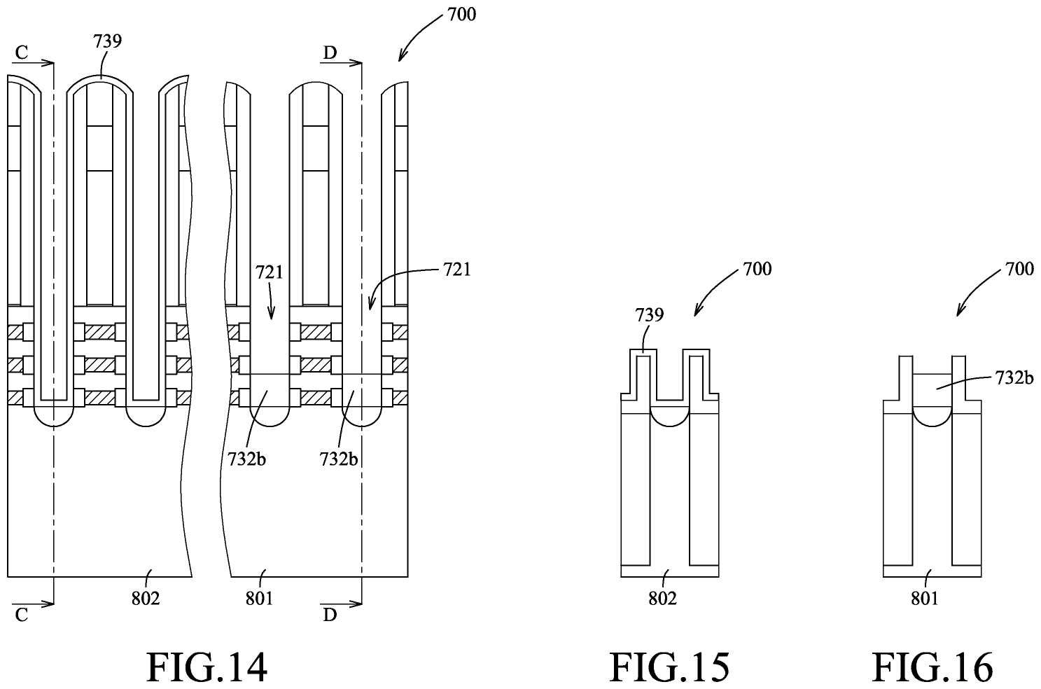

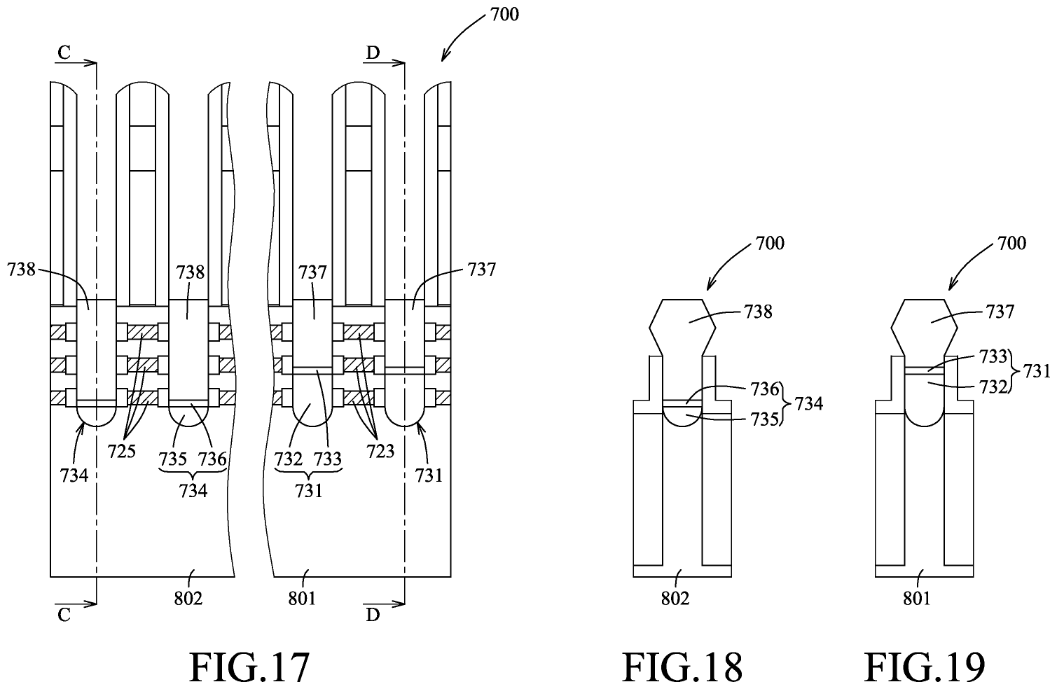

Referring to FIGS. 5 and 12 to 19, where FIG. 13 is a view similar to FIG. 7, FIG. 15 and FIG. 16 are schematic sectional views taken respectively along line C-C and line D-D of FIG. 14, and FIG. 18 and FIG. 19 are schematic sectional views taken respectively along line C-C and line D-D of FIG. 17, the method 200 then proceeds to step S24, where two isolation elements 731 are respectively formed in the first source/drain recesses 721, two filled elements 734 are respectively formed in the second source/drain recesses 722, two first source/drain regions 737 are respectively formed in the first source/drain recesses 721 to cover the isolation elements 731, and two second source/drain regions 738 are respectively formed in the second source/drain recesses 722 to cover the filled elements 734. As shown in FIGS. 17 and 19, each of the isolation elements 731 includes a first isolation segment 732, and a second isolation segment 733 disposed between the first isolation segment 732 and the respective one of the first source/drain regions 737; and an upper surface of each of the isolation elements 731 is not higher than a lower surface of a topmost one of the first channel layers 723, and is not lower than an upper surface of a bottommost one of the first channel layers 723. FIGS. 17 and 19 depict an example where the upper surface of each of the isolation elements 731 is not higher than the lower surface of a second topmost one of the first channel layers 723, and is not lower than the upper surface of the bottommost one of the first channel layers 723. As shown in FIGS. 17 and 18, each of the filled elements 734 includes a first filled segment 735, and a second filled segment 736 disposed between the first filled segment 735 and the respective one of the second source/drain regions 738; and an upper surface of each of the filled elements 734 is not higher than a lower surface of a bottommost one of the second channel layers 725, so each of the filled elements 734 is kept away from contact with the second channel layers 725. In some embodiments, the isolation elements 731, the filled elements 734 and the first and second source/drain regions 737, 738 may be formed by: (a) as shown in FIGS. 12 and 13, epitaxially forming lower portions (732a) of the first isolation segments 732 of the isolation elements 731 (see FIGS. 17 and 19) and the first filled segments 735 of the filled elements 734 (see FIGS. 17 and 18) using, for example, cyclic deposition-etch (CDE) process, other suitable techniques, or combinations thereof; (b) as shown in FIGS. 14, 15 and 16, forming a patterned mask layer 739 over a portion of the semiconductor structure 700 depicted in FIGS. 12 and 13 that is formed over the second region 802; (c) as shown in FIGS. 14, 15 and 16, epitaxially forming upper portions (732b) of the first isolation segments 732 (see FIGS. 17 and 19) using, for example, CDE process, other suitable techniques, or combinations thereof; (d) removing the patterned mask layer 739; (e) as shown in FIGS. 17, 18 and 19, forming the second isolation segments 733 of the isolation elements 731 and the second filled segments 736 of the filled elements 734 using, for example, CVD that has a cyclic process including deposition, plasma treatment and etching, other suitable techniques, or combinations thereof; and (f) as shown in FIGS. 17, 18 and 19, epitaxially forming the first and second source/drain regions 737, 738 using, for example, CDE process, other suitable techniques, or combinations thereof. In some embodiments, each of the first isolation segments 732 and the first filled segments 735 may include, for example, un-doped silicon, other suitable un-doped semiconductor materials, or combinations thereof. In some embodiments, each of the second isolation segments 733 and the second filled segments 736 may include, for example, silicon nitride, silicon oxycarbide, silicon oxycarbonitride, silicon carbonitride, other suitable dielectric materials, or combinations thereof. In some embodiments, the first and second source/drain regions 737, 738 may include, for example, crystalline silicon (or other suitable materials) doped with an n-type impurity or a p-type impurity. The first and second isolation segments 732, 733 of each of the isolation elements 731 would respectively serve as the first and second isolation segments 121, 122 of a corresponding one of the isolation elements 12 (see FIGS. 2 and 4). The first and second filled segments 735, 736 of each of the filled elements 734 would respectively serve as the first and second filled segments 221, 222 of a corresponding one of the filled elements 22 (see FIGS. 1 and 3). The first source/drain regions 737 would serve as the first source/drain regions 11 (see FIGS. 2 and 4). The second source/drain regions 738 would serve as the second source/drain regions 21 (see FIGS. 1 and 3). The first channel layer(s) 723 which is/are disposed between the isolation elements 731 serve(s) as the at least one dummy channel layer 132 (see FIGS. 2 and 4). The first channel layer(s) 723 which is/are disposed between the first source/drain regions 737 serve(s) as the at least one first effective channel layer 131 (see FIGS. 2 and 4). In the example depicted in FIGS. 17 and 19, the bottommost one of the first channel layers 723 serves as the dummy channel layer, and the two topmost ones of the first channel layers 723 serve as the first effective channel layers. The second channel layers 725, each of which is disposed between the second source/drain regions 738, serve as the second effective channel layers 231 (see FIGS. 1 and 3).

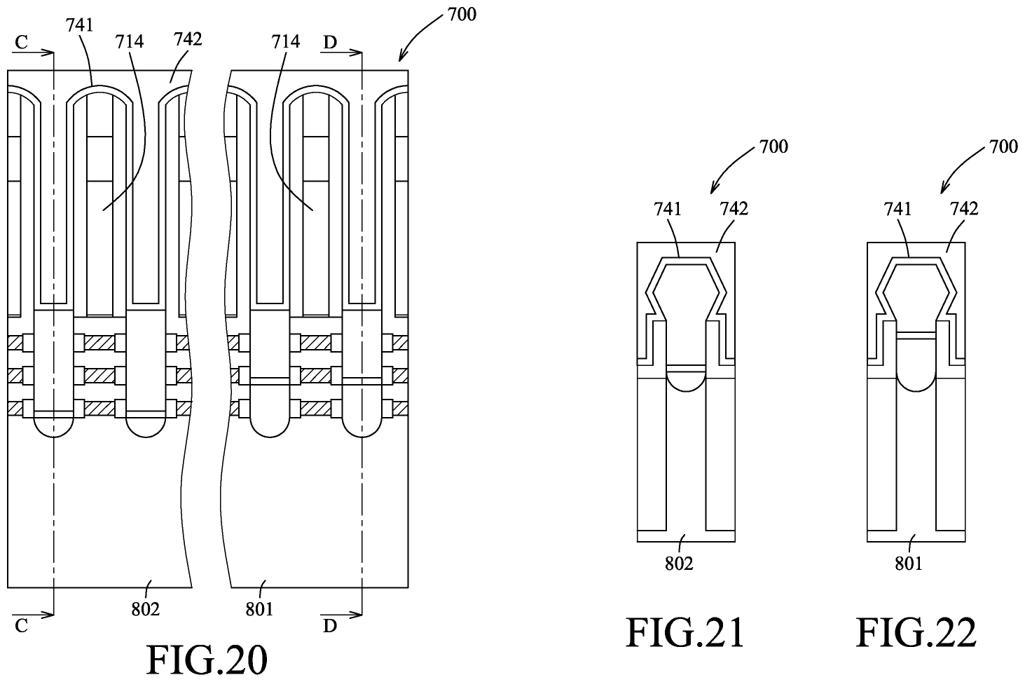

Referring to FIGS. 5, 20, 21 and 22, where FIGS. 21 and 22 are schematic sectional views taken respectively along line C-C and line D-D f FIG. 20, the method 200 then proceeds to step S25, where an etch stop layer 741 and an interlayer dielectric 742 are sequentially formed over the semiconductor structure 700 depicted in FIGS. 17, 18 and 19. In some embodiments, the etch stop layer 741 may be conformally formed using, for example, CVD, ALD, other suitable techniques, or combinations thereof. In some embodiments, the interlayer dielectric 742 may be formed using, for example, CVD, PECVD, PVD, ALD, other suitable techniques, or combinations thereof. In some embodiments, the etch stop layer 741 may include, for example, aluminum compounds (e.g., aluminum nitride, aluminum oxynitride, aluminum oxide, etc.), silicon compounds (e.g., silicon oxide, silicon oxycarbide, silicon carbonitride, silicon nitride, silicon oxycarbonitride, etc.), other suitable materials, or combinations thereof. In some embodiments, the interlayer dielectric 742 may include, for example, silicon oxide, silicon nitride, silicon oxynitride, phosphosilicate glass (PSG), borophosphosilicate glass (BPSG), spin-on glass (SOG), fluorosilicate glass (FSG), carbon-doped silicon oxide (e.g., SiCOH), xerogel, aerogel, parylene, divinylsiloxane-bis-benzocyclobutene-based (BCB-based) dielectric material, polyimide, other suitable material, or combinations thereof.

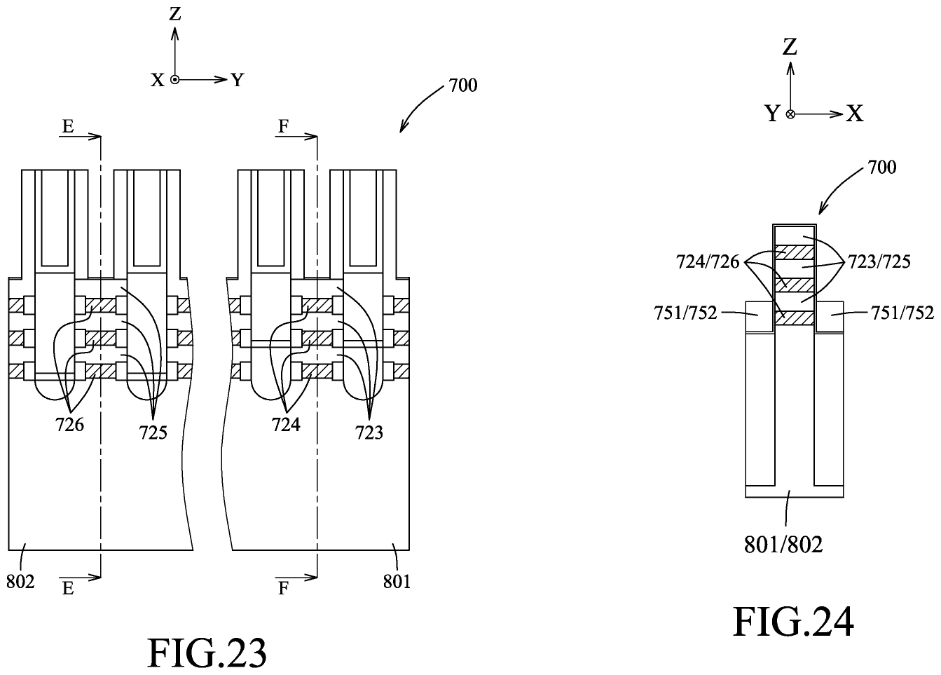

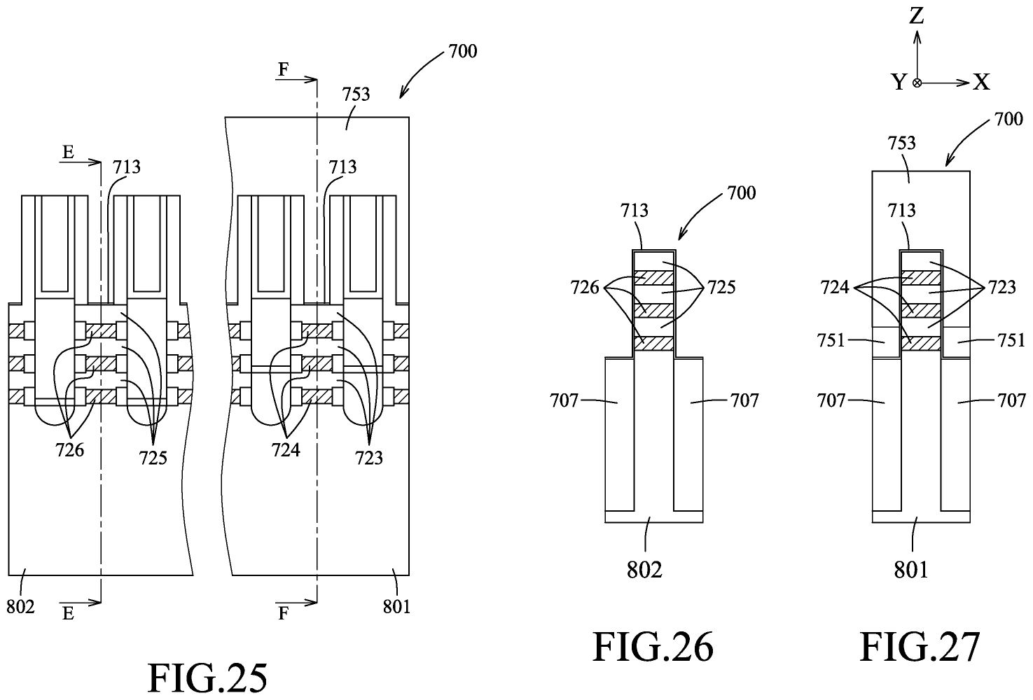

Referring to FIGS. 5 and 20 to 27, where FIG. 24 illustrates a schematic sectional view taken along any one of line E-E and line F-F of FIG. 23, and FIGS. 26 and 27 are schematic sectional views taken respectively along line E-E and line F-F of FIG. 25, the method 200 then proceeds to step S26, where two protection elements 751 are formed. As shown in FIG. 27, the protection elements 751 are spaced apart by a combination of the layers 723, 724 in the X direction; and an upper surface of each of the protection elements 751 is not higher than an upper surface of a topmost one of those first channel layer(s) 723 serving as the dummy channel layer(s), and is not lower than a lower surface of the topmost one of those first channel layer(s) 723 serving as the dummy channel layer(s). FIGS. 25, 26 and 27 depict an example where the upper surface of each of the protection elements 751 is not higher than the upper surface of the bottommost one of the first channel layers 723 that serves as the dummy channel layer, and is not lower than the lower surface of the bottommost one of the first channel layers 723 that serves as the dummy channel layer. In some embodiments, step S26 may be implemented as described below. First, the semiconductor structure 700 depicted in FIGS. 20, 21 and 22 is subjected to a planarization treatment (e.g., CMP) to expose top surfaces of the dummy gate electrodes 714. Next, the dummy gate electrodes 714 are etched back using, for example, dry etching, wet etching, RIE, ALE, other suitable techniques, or combinations thereof, so as to form the protection elements 751 and another two protection elements 752, where the protection elements 751 are respectively disposed at two opposite sides of the combination of the layers 723, 724 in the X direction and the protection elements 752 are respectively disposed at two opposite sides of a combination of the layers 725, 726 in the X direction as shown in FIG. 24. Then, as shown in FIGS. 25, 26 and 27, a patterned photoresist layer 753 is formed over a portion of the semiconductor structure 700 depicted in FIGS. 23 and 24 that is disposed over the first region 801. Subsequently, the protection elements 752 are removed using, for example, dry etching, wet etching, RIE, ALE, other suitable techniques, or combinations thereof. Lastly, the patterned photoresist layer 753 is removed. In some embodiments, a distance between the upper surface of each of the protection elements 751 and the upper surface of a respective one of the STIs 707 may fall within a range of from 15 nm to 30 nm. In some embodiments, a distance between the upper surface of each of the protection elements 751 and the upper surface of the topmost one of those first channel layer(s) 723 serving as the dummy channel layer(s) may be half the thickness of each of the first semiconductor sheets for forming the channel films 705 (see FIGS. 6 and 7), and may fall within a range of from 2 nm to 5 nm.

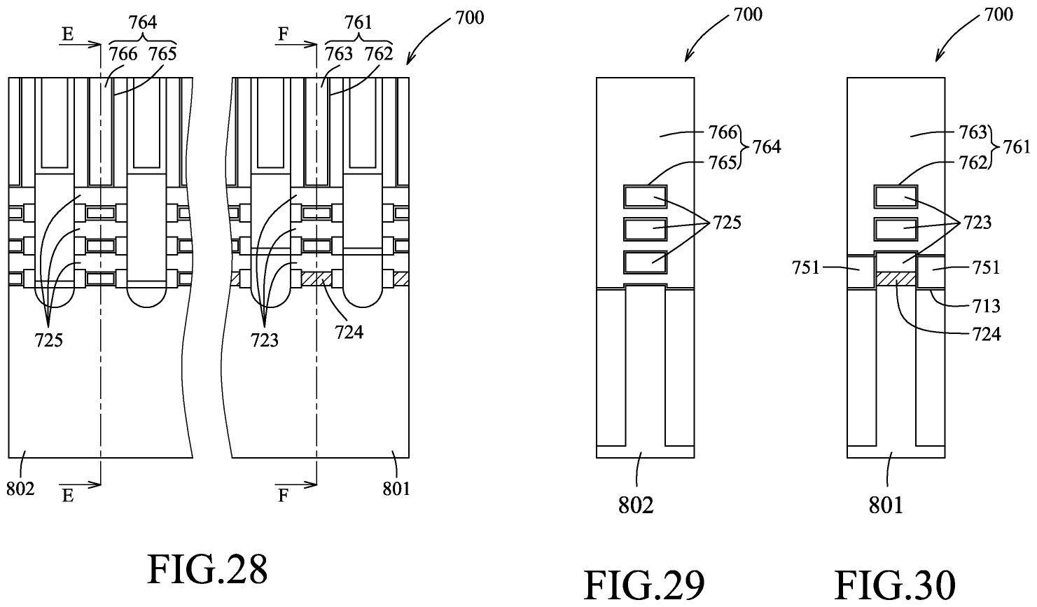

Referring to FIGS. 5 and 25 to 30, where FIGS. 29 and 30 are schematic sectional views taken respectively along line E-E and line F-F—of FIG. 28, the method 200 then proceeds to step S27, where the first semiconductor layer(s) 724 exposed from the protection elements 751, the second semiconductor layers 726 and portions of the dummy gate dielectrics 713 exposed from the protection elements 751 are removed, a first gate feature 761 is formed around the first channel layer(s) 723 thus exposed, and a second gate feature 764 is formed around the second channel layers 725 thus exposed. The first gate feature 761 includes a first gate dielectric 762 that is formed on the first channel layer(s) 723 thus exposed, and a first gate electrode 763 that is formed to surround the first channel layer(s) 723 covered by the first gate dielectric 762. The second gate feature 764 includes a second gate dielectric 765 that is formed on the second channel layers 725 thus exposed, and a second gate electrode 766 that is formed to surround the second channel layers 725 covered by the second gate dielectric 765. In some embodiments, the first semiconductor layer(s) 724 exposed from the protection elements 751, the second semiconductor layers 726 and the portions of the dummy gate dielectrics 713 exposed from the protection elements 751 may be removed using, for example, drying etching, wet etching, RIE, ALE, other suitable techniques, or combinations thereof. In some embodiments, the first and second gate dielectrics 762, 765 and the first and second gate electrodes 763, 766 may be formed using, for example, PVD. CVD, ALD, other suitable techniques, or combinations thereof. In some embodiments, each of the first and second gate dielectrics 762, 765 may include, for example, Hf-based dielectric materials, Zr-based dielectric materials, Al-based dielectric materials. Ti-based dielectric materials, Ba-based dielectric materials, RE element-based dielectric materials, nitrides, other suitable high dielectric constant materials, or combinations thereof. In some embodiments, each of the first and second gate electrodes 763, 766 may include, for example, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), other suitable conductive materials, or combinations thereof. The remaining first semiconductor layer(s) 724 would serve as the at least one semiconductor layer 14 (see FIGS. 2 and 4). FIGS. 25 to 30 depict an example where a bottommost one of the first semiconductor layers 724 remains and covers the lower surface of the bottommost one of the first channel layers 723 that serves as the dummy channel layer. The first gate dielectric 762 and the first gate electrode 763 of the first gate feature 761 would respectively serve as the first gate dielectric 151 and the first gate electrode 152 of the first gate feature 15 (see FIGS. 2 and 4). The second gate dielectric 765 and the second gate electrode 766 of the second gate feature 764 would respectively serve as the second gate dielectric 251 and the second gate electrode 252 of the second gate feature 25 (see FIGS. 1 and 3).

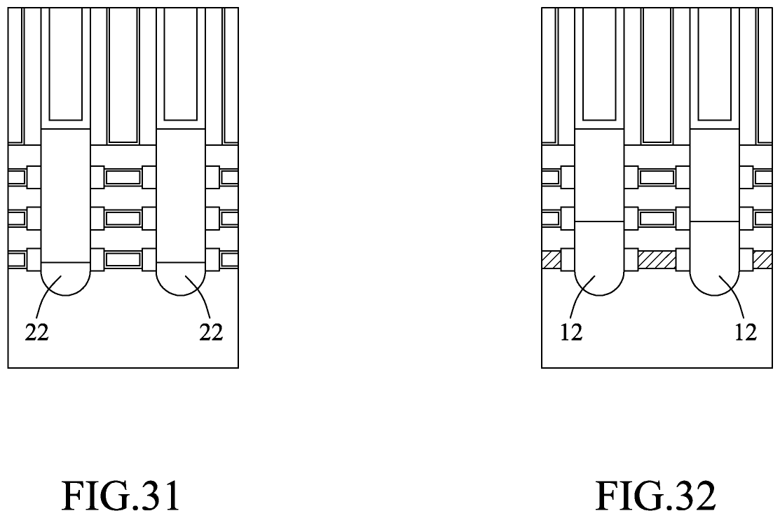

FIGS. 31 and 32 are schematic sectional views cooperatively showing a semiconductor structure in accordance with some embodiments. The semiconductor structure cooperatively depicted in FIGS. 31 and 32 is similar to the semiconductor structure cooperatively depicted in FIGS. 1 and 2, but differs from the semiconductor structure cooperatively depicted in FIGS. 1 and 2 in the configurations of the isolation elements 12 and the filled elements 22. With respect to the semiconductor structure cooperatively depicted in FIGS. 31 and 32, each of the isolation elements 12 and the filled elements 22 is wholly made of an un-doped semiconductor material (e.g., un-doped silicon) or a dielectric material (e.g., silicon nitride, silicon oxycarbide, silicon oxycarbonitride or silicon carbonitride).

A method for manufacturing the semiconductor structure cooperatively depicted in FIGS. 31 and 32 is similar to the method 200 shown in FIG. 5, but differs from the method 200 shown in FIG. 5 in the way of forming the isolation elements 12 and the filled elements 22 in step S24. With respect to the method for manufacturing the semiconductor structure cooperatively depicted in FIGS. 31 and 32, the isolation elements 12 and the filled elements 22 may be formed by: (a) forming lower portions of the isolation elements 12 and the filled elements 22 using, for example, CDE process, other suitable techniques, or combinations thereof; (b) forming a patterned mask layer to at least cover the filled elements 22; (c) forming upper portions of the isolation elements 12 using, for example, CDE process, other suitable techniques, or combinations thereof; and (d) removing the patterned mask layer.

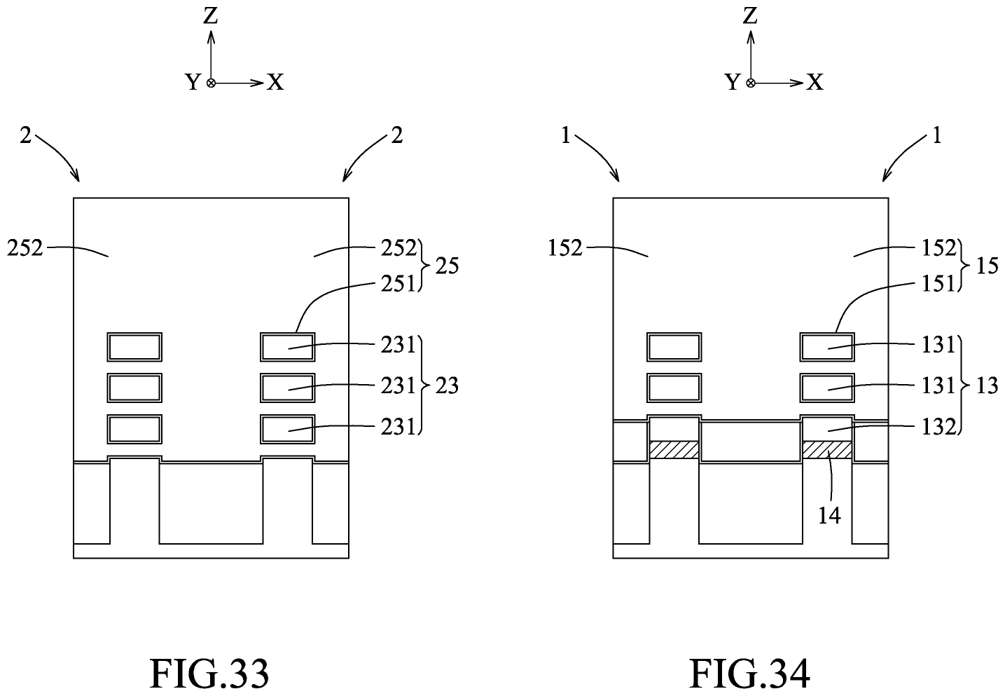

FIGS. 33 and 34 are schematic sectional views cooperatively showing a semiconductor structure in accordance with some embodiments. The semiconductor structure cooperatively depicted in FIGS. 33 and 34 is similar to the semiconductor structure cooperatively depicted in FIGS. 3 and 4, but differs from the semiconductor structure cooperatively depicted in FIGS. 3 and 4 in that the semiconductor structure cooperatively depicted in FIGS. 33 and 34 includes two first devices 1 and two second devices 2. With respect to the semiconductor structure cooperatively depicted in FIGS. 33 and 34, the first devices 1 are adjacent to each other in the X direction, with the first gate electrodes 152 of the first devices 1 in contact with each other, and the second devices 2 are adjacent to each other in the X direction, with the second gate electrodes 252 of the second devices 2 in contact with each other.

In accordance with some embodiments of the present disclosure, a semiconductor device includes two source/drain regions, two isolation elements, a channel feature, at least one semiconductor layer and a gate feature. The source/drain regions are spaced apart from each other in a first direction transverse to a second direction from bottom to top of the semiconductor device. Each of the isolation elements is disposed below a respective one of the source/drain regions. The channel feature includes at least one effective channel layer and at least one dummy channel layer that are spaced apart from each other in the second direction. Each of the at least one effective channel layer extends between the two source/drain regions. Each of the at least one dummy channel layer extends between the two isolation elements. The at least one semiconductor layer at least covers a lower surface of a bottommost one of the at least one dummy channel layer. The gate feature is disposed around the at least one effective channel layer such that two surfaces of each of the at least one effective channel layer, which are opposite to each other in the second direction, are adjacent to the gate feature.

In accordance with some embodiments of the present disclosure, each of the isolation elements is made of an un-doped semiconductor material or a dielectric material.

In accordance with some embodiments of the present disclosure, each of the isolation elements includes a first isolation segment that is made of an un-doped semiconductor material, and a second isolation segment that is disposed between the first isolation segment and the respective one of the source/drain regions and that is made of a dielectric material.

In accordance with some embodiments of the present disclosure, the dielectric material is selected from silicon nitride, silicon oxycarbide, silicon oxycarbonitride, silicon carbonitride, or combinations thereof.

In accordance with some embodiments of the present disclosure, a thickness of the second isolation segment of each of the isolation elements is smaller than a thickness of each of the at least one effective channel layer and the at least one dummy channel layer.

In accordance with some embodiments of the present disclosure, a semiconductor structure includes a first device and a second device. The first device includes two first source/drain regions, two isolation elements, a first channel feature, at least one semiconductor layer and a first gate feature. The first source/drain regions are spaced apart from each other in a first direction transverse to a second direction from bottom to top of the semiconductor structure. Each of the isolation elements is disposed below a respective one of the first source/drain regions. The first channel feature includes at least one first effective channel layer and at least one dummy channel layer that are spaced apart from each other in the second direction. Each of the at least one first effective channel layer extends between the two first source/drain regions. Each of the at least one dummy channel layer extends between the two isolation elements. The at least one semiconductor layer at least covers a lower surface of a bottommost one of the at least one dummy channel layer. The first gate feature is disposed around the at least one first effective channel layer such that two surfaces of each of the at least one first effective channel layer, which are opposite to each other in the second direction, are adjacent to the first gate feature. The second device includes two second source/drain regions, a second channel feature and a second gate feature. The second source/drain regions are spaced apart from each other in the first direction. The second channel feature includes a plurality of second effective channel layers that are spaced apart from each other in the second direction. Each of the second effective channel layers extends between the two second source/drain regions. A total number of the second effective channel layers is equal to a total number of the at least one first effective channel layer and the at least one dummy channel layer. The second gate feature is disposed around the second effective channel layers such that two surfaces of each of the second effective channel layers, which are opposite to each other in the second direction, are adjacent to the second gate structure.

In accordance with some embodiments of the present disclosure, each of the isolation elements is made of an un-doped semiconductor material or a dielectric material.

In accordance with some embodiments of the present disclosure, each of the isolation elements includes a first isolation segment that is made of an un-doped semiconductor material, and a second isolation segment that is disposed between the first isolation segment and the respective one of the first source/drain regions and that is made of a dielectric material.

In accordance with some embodiments of the present disclosure, the dielectric material is selected from silicon nitride, silicon oxycarbide, silicon oxycarbonitride, silicon carbonitride, or combinations thereof.

In accordance with some embodiments of the present disclosure, a thickness of the second isolation segment of each of the isolation elements is smaller than a thickness of each of the at least one first effective channel layer and the at least one dummy channel layer.

In accordance with some embodiments of the present disclosure, the second device further includes two filled elements, each of which is disposed below a respective one of the second source/drain regions and is kept away from contact with the second effective channel layers.

In accordance with some embodiments of the present disclosure, each of the filled elements includes a first filled segment that is made of an un-doped semiconductor material, and a second filled segment that is disposed between the first filled segment and the respective one of the second source/drain regions and that is made of a dielectric material.

In accordance with some embodiments of the present disclosure, the dielectric material is selected from silicon nitride, silicon oxycarbide, silicon oxycarbonitride, silicon carbonitride, or combinations thereof.

In accordance with some embodiments of the present disclosure, a method for manufacturing a semiconductor structure includes: forming a first device; and forming a second device. The first device includes two first source/drain regions, two isolation elements, a first channel feature, at least one semiconductor layer and a first gate feature. The first source/drain regions are spaced apart from each other in a first direction transverse to a second direction from bottom to top of the first device. Each of the isolation elements is disposed below a respective one of the first source/drain regions. The first channel feature includes at least one first effective channel layer and at least one dummy channel layer that are spaced apart from each other in the second direction. Each of the at least one first effective channel layer extends between the two first source/drain regions. Each of the at least one dummy channel layer extends between the two isolation elements. The at least one semiconductor layer at least covers a lower surface of a bottommost one of the at least one dummy channel layer. The first gate feature is disposed around the at least one first effective channel layer such that two surfaces of each of the at least one first effective channel layer, which are opposite to each other in the second direction, are adjacent to the first gate feature. The second device includes two second source/drain regions, a second channel feature and a second gate feature. The second source/drain regions are spaced apart from each other in the first direction. The second channel feature includes a plurality of second effective channel layers that are spaced apart from each other in the second direction. Each of the second effective channel layers extends between the two second source/drain regions. A total number of the second effective channel layers is equal to a total number of the at least one first effective channel layer and the at least one dummy channel layer. The second gate feature is disposed around the second effective channel layers such that two surfaces of each of the second effective channel layers, which are opposite to each other in the second direction, are adjacent to the second gate structure.

In accordance with some embodiments of the present disclosure, the first device and the second device are formed by: forming a plurality of stack units, each of the stack units including a first stack and a second stack, each of which includes a channel film and a semiconductor film disposed below the channel film; forming, in the first stacks of the stack units, two first source/drain recesses that are spaced apart from each other in the first direction, so that the channel films of the first stacks of the stack units are formed into first channel layers and the semiconductor films of the first stacks of the stack units are formed into first semiconductor layers; forming, in the second stacks of the stack units, two second source/drain recesses that are spaced apart from each other in the first direction, so that the channel films of the second stacks of the stack units are formed into second channel layers and the semiconductor films of the second stacks of the stack units are formed into second semiconductor layers; forming the isolation elements of the first device respectively in the first source/drain recesses, where an upper surface of each of the isolation elements is not higher than a lower surface of a topmost one of the first channel layers and is not lower than an upper surface of a bottommost one of the first channel layers, so that each of those of the first channel layers that is disposed between the isolation elements serves as one of the at least one dummy channel layer of the first device; forming the first source/drain regions of the first device respectively in the first source/drain recesses to cover the isolation elements, so that each of those of the first channel layers that is disposed between the first source/drain regions serves as one of the at least one first effective channel layer of the first device; forming the second source/drain regions of the second device respectively in the second source/drain recesses, so that the second channel layers are disposed between the second source/drain regions and serve as the second effective channel layers of the second device; forming two protection elements that are spaced apart by the first stacks of the stack units in a third direction transverse to the first direction and the second direction, where an upper surface of each of the protection elements is not higher than an upper surface of a topmost one of the at least one dummy channel layer and is not lower than a lower surface of the topmost one of the at least one dummy channel layer; removing the first semiconductor layer(s) that is (are) not disposed between the protection elements, so that the first semiconductor layer(s) that is (are) disposed between the protection elements serve(s) as the at least one semiconductor layer of the first device; removing the second semiconductor layers; forming the first gate structure of the first device around the at least one first effective channel layer; and forming the second gate structure of the second device around the second effective channel layers.

In accordance with some embodiments of the present disclosure, the second device further includes two filled elements, each of which is disposed below a respective one of the second source/drain regions and is kept away from contact with the second effective channel layers; the second device is further formed by, after forming the second source/drain recesses and before forming the second source/drain regions, forming the filled elements of the second device respectively in the second source/drain recesses, where an upper surface of each of the filled elements is not higher than a lower surface of a bottommost one of the second effective channel layers; and each of the filled elements includes a first filled segment that is made of an un-doped semiconductor material, and a second filled segment that is disposed between the first filled segment and the respective one of the second source/drain regions and that is made of a dielectric material.

In accordance with some embodiments of the present disclosure, the dielectric material is selected from silicon nitride, silicon oxycarbide, silicon oxycarbonitride, silicon carbonitride, or combinations thereof.

In accordance with some embodiments of the present disclosure, each of the isolation elements is made of an un-doped semiconductor material or a dielectric material.

In accordance with some embodiments of the present disclosure, each of the isolation elements includes a first isolation segment that is made of an un-doped semiconductor material, and a second isolation segment that is disposed between the first isolation segment and the respective one of the first source/drain regions and that is made of a dielectric material.

In accordance with some embodiments of the present disclosure, the dielectric material is selected from silicon nitride, silicon oxycarbide, silicon oxycarbonitride, silicon carbonitride, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
two source/drain regions spaced apart from each other in a first direction transverse to a second direction from bottom to top of the semiconductor device;
two isolation elements, each of which is disposed below a respective one of the source/drain regions;
a channel feature including at least one effective channel layer and at least one dummy channel layer that are spaced apart from each other in the second direction, each of the at least one effective channel layer extending between the two source/drain regions, each of the at least one dummy channel layer extending between the two isolation elements;
at least one semiconductor layer at least covering a lower surface of a bottommost one of the at least one dummy channel layer; and
a gate feature disposed around the at least one effective channel layer such that two surfaces of each of the at least one effective channel layer, which are opposite to each other in the second direction, are adjacent to the gate feature.

2. The semiconductor device according to claim 1, wherein each of the isolation elements is made of an un-doped semiconductor material or a dielectric material.

3. The semiconductor device according to claim 1, wherein each of the isolation elements includes a first isolation segment that is made of an un-doped semiconductor material, and a second isolation segment that is disposed between the first isolation segment and the respective one of the source/drain regions and that is made of a dielectric material.

4. The semiconductor device according to claim 3, wherein the dielectric material is selected from silicon nitride, silicon oxycarbide, silicon oxycarbonitride, silicon carbonitride, or combinations thereof.

5. The semiconductor device according to claim 3, wherein a thickness of the second isolation segment of each of the isolation elements is smaller than a thickness of each of the at least one effective channel layer and the at least one dummy channel layer.

6. A semiconductor structure comprising:
a first device including
two first source/drain regions spaced apart from each other in a first direction transverse to a second direction from bottom to top of the semiconductor structure,
two isolation elements, each of which is disposed below a respective one of the first source/drain regions,
a first channel feature including at least one first effective channel layer and at least one dummy channel layer that are spaced apart from each other in the second direction, each of the at least one first effective channel layer extending between the two first source/drain regions, each of the at least one dummy channel layer extending between the two isolation elements,
at least one semiconductor layer at least covering a lower surface of a bottommost one of the at least one dummy channel layer, and
a first gate feature disposed around the at least one first effective channel layer such that two surfaces of each of the at least one first effective channel layer, which are opposite to each other in the second direction, are adjacent to the first gate feature; and
a second device including
two second source/drain regions spaced apart from each other in the first direction,
a second channel feature including a plurality of second effective channel layers that are spaced apart from each other in the second direction, each of the second effective channel layers extending between the two second source/drain regions, a total number of the second effective channel layers being equal to a total number of the at least one first effective channel layer and the at least one dummy channel layer, and
a second gate feature disposed around the second effective channel layers such that two surfaces of each of the second effective channel layers, which are opposite to each other in the second direction, are adjacent to the second gate structure.

7. The semiconductor structure according to claim 6, wherein each of the isolation elements is made of an un-doped semiconductor material or a dielectric material.

8. The semiconductor structure according to claim 6, wherein each of the isolation elements includes a first isolation segment that is made of an un-doped semiconductor material, and a second isolation segment that is disposed between the first isolation segment and the respective one of the first source/drain regions and that is made of a dielectric material.

9. The semiconductor structure according to claim 8, wherein the dielectric material is selected from silicon nitride, silicon oxycarbide, silicon oxycarbonitride, silicon carbonitride, or combinations thereof.

10. The semiconductor structure according to claim 8, wherein a thickness of the second isolation segment of each of the isolation elements is smaller than a thickness of each of the at least one first effective channel layer and the at least one dummy channel layer.

11. The semiconductor structure according to claim 6, wherein the second device further includes two filled elements, each of which is disposed below a respective one of the second source/drain regions and is kept away from contact with the second effective channel layers.

12. The semiconductor structure according to claim 11, wherein each of the filled elements includes a first filled segment that is made of an un-doped semiconductor material, and a second filled segment that is disposed between the first filled segment and the respective one of the second source/drain regions and that is made of a dielectric material.

13. The semiconductor structure according to claim 12, wherein the dielectric material is selected from silicon nitride, silicon oxycarbide, silicon oxycarbonitride, silicon carbonitride, or combinations thereof.

14. A method for manufacturing a semiconductor structure, comprising:
forming a first device that includes
two first source/drain regions spaced apart from each other in a first direction transverse to a second direction from bottom to top of the first device,
two isolation elements, each of which is disposed below a respective one of the first source/drain regions,
a first channel feature including at least one first effective channel layer and at least one dummy channel layer that are spaced apart from each other in the second direction, each of the at least one first effective channel layer extending between the two first source/drain regions, each of the at least one dummy channel layer extending between the two isolation elements,
at least one semiconductor layer at least covering a lower surface of a bottommost one of the at least one dummy channel layer, and
a first gate feature disposed around the at least one first effective channel layer such that two surfaces of each of the at least one first effective channel layer, which are opposite to each other in the second direction, are adjacent to the first gate feature; and
forming a second device that includes
two second source/drain regions spaced apart from each other in the first direction,
a second channel feature including a plurality of second effective channel layers that are spaced apart from each other in the second direction, each of the second effective channel layers extending between the two second source/drain regions, a total number of the second effective channel layers being equal to a total number of the at least one first effective channel layer and the at least one dummy channel layer, and
a second gate feature disposed around the second effective channel layers such that two surfaces of each of the second effective channel layers, which are opposite to each other in the second direction, are adjacent to the second gate structure.

15. The method according to claim 14, wherein the first device and the second device are formed by:
forming a plurality of stack units, each of the stack units including a first stack and a second stack, each of which includes a channel film and a semiconductor film disposed below the channel film;
forming, in the first stacks of the stack units, two first source/drain recesses that are spaced apart from each other in the first direction, so that the channel films of the first stacks of the stack units are formed into first channel layers and the semiconductor films of the first stacks of the stack units are formed into first semiconductor layers;
forming, in the second stacks of the stack units, two second source/drain recesses that are spaced apart from each other in the first direction, so that the channel films of the second stacks of the stack units are formed into second channel layers and the semiconductor films of the second stacks of the stack units are formed into second semiconductor layers;
forming the isolation elements of the first device respectively in the first source/drain recesses, where an upper surface of each of the isolation elements is not higher than a lower surface of a topmost one of the first channel layers and is not lower than an upper surface of a bottommost one of the first channel layers, so that each of those of the first channel layers that is disposed between the isolation elements serves as one of the at least one dummy channel layer of the first device;
forming the first source/drain regions of the first device respectively in the first source/drain recesses to cover the isolation elements, so that each of those of the first channel layers that is disposed between the first source/drain regions serves as one of the at least one first effective channel layer of the first device;
forming the second source/drain regions of the second device respectively in the second source/drain recesses, so that the second channel layers are disposed between the second source/drain regions and serve as the second effective channel layers of the second device;
forming two protection elements that are spaced apart by the first stacks of the stack units in a third direction transverse to the first direction and the second direction, where an upper surface of each of the protection elements is not higher than an upper surface of a topmost one of the at least one dummy channel layer and is not lower than a lower surface of the topmost one of the at least one dummy channel layer;
removing the first semiconductor layer(s) that is (are) not disposed between the protection elements, so that the first semiconductor layer(s) that is (are) disposed between the protection elements serve(s) as the at least one semiconductor layer of the first device;
removing the second semiconductor layers;
forming the first gate structure of the first device around the at least one first effective channel layer; and
forming the second gate structure of the second device around the second effective channel layers.

16. The method according to claim 15, wherein:
the second device further includes two filled elements, each of which is disposed below a respective one of the second source/drain regions and is kept away from contact with the second effective channel layers;
the second device is further formed by, after forming the second source/drain recesses and before forming the second source/drain regions, forming the filled elements of the second device respectively in the second source/drain recesses, where an upper surface of each of the filled elements is not higher than a lower surface of a bottommost one of the second effective channel layers; and
each of the filled elements includes a first filled segment that is made of an un-doped semiconductor material, and a second filled segment that is disposed between the first filled segment and the respective one of the second source/drain regions and that is made of a dielectric material.

17. The semiconductor structure according to claim 16, wherein the dielectric material is selected from silicon nitride, silicon oxycarbide, silicon oxycarbonitride, silicon carbonitride, or combinations thereof.

18. The method according to claim 14, wherein each of the isolation elements is made of an un-doped semiconductor material or a dielectric material.

19. The method according to claim 14, wherein each of the isolation elements includes a first isolation segment that is made of an un-doped semiconductor material, and a second isolation segment that is disposed between the first isolation segment and the respective one of the first source/drain regions and that is made of a dielectric material.

20. The method according to claim 19, wherein the dielectric material is selected from silicon nitride, silicon oxycarbide, silicon oxycarbonitride, silicon carbonitride, or combinations thereof.
